(19) United States
(12) Patent Application Publication
(10) Pub. No.: US 2008/0278183 A1
(43) Pub. Date: Nov. 13, 2008

(54) FUEL CELL TEST SYSTEM

(75) Inventors: Douglas A. McClelland, Springboro, OH (US); Daniel P. Kramer, Centerville, OH (US)

Correspondence Address: THOMPSON HINE L.L.P.;Intellectual Property Group, P.O. BOX 8801, DAYTON, OH, 45401-8801, US

(73) Assignee: MOUND TECHNICAL SOLUTIONS, INC., Miamisburg, OH (US)

(21) Appl. No.: 12/098,798

(22) Filed: Apr. 7, 2008

Related U.S. Application Data
(60) Provisional application No. 60/927,988, filed on May 7, 2007.

(51) Int. Cl. G01R 31/40

(52) U.S. Cl. 324/713; 324/721

(57) ABSTRACT

A fuel cell test system including a controller, a housing defining a test chamber, a test subject fuel cell positioned in the test chamber, the test subject fuel cell being in communication with the controller to provide the controller with signals indicative of a performance of the test subject fuel cell, a fuel feed in communication with the test subject fuel cell, the fuel feed having a humidity, a flow rate and a pressure, wherein at least one of the humidity, the flow rate and the pressure of the fuel feed is controllable by the controller, and an oxidant feed in communication with the test subject fuel cell, the oxidant feed having a humidity, a flow rate and a pressure, wherein at least one of the humidity, the flow rate and the pressure of the oxidant feed is controllable by the controller, wherein the controller monitors the performance of the test subject fuel cell in response to the fuel feed and the oxidant feed.

The present patent application claims priority from U.S. Ser. No. 60/927,988 filed on May 7, 2007, the entire contents of which are incorporated herein by reference.

### BACKGROUND

The present disclosure is directed to a fuel cell test system and, more particularly, to a fuel cell test system and associated apparatus incorporating an integral heated fuel cell test chamber.

Fuel cell test systems have been developed to perform various functions, such as facilitating the operation of a test subject fuel cell by supplying controlled amounts of fuel and oxidant to the test subject fuel cell, humidifying the gaseous fuel and oxidant streams being supplied to the test subject fuel cell and evaluating the performance of the test subject fuel cell by measuring the current, voltage and/or other operational characteristics generated by the test subject fuel cell under operating conditions.

Fuel cell test systems typically employ elongated supply or feed lines to connect the fuel cell test system to an external test subject fuel cell. The external test subject fuel cell may be heated by cartridge heaters or the like to the desired operating temperature. However, such systems may develop cold spots in the test subject fuel cell or the supply lines supplying the fuel and/or oxidant from the fuel cell test system to the test subject fuel cell, which may cause condensate formation in the supply lines. Condensate formation may adversely impact the reliability of the test data.

Accordingly, there is a need for a fuel cell test system capable of avoiding the problems associated with condensate formation in the test subject fuel cell and/or the feedstock supply lines supplying fuel and oxidant to the test subject fuel cell. In particular, there is a need for a fuel cell test system having an integral heated test chamber capable of receiving and maintaining the test subject fuel cell and associated feedstock supply lines at the desired temperature, thereby reducing the risk of condensate formation and other negative implications associated with temperature variation.

### SUMMARY

In one aspect, the disclosed fuel cell test system may include a controller, a housing defining a test chamber, a test subject fuel cell positioned in the test chamber, the test subject fuel cell being in communication with the controller to provide the controller with signals indicative of a performance of the test subject fuel cell, a fuel feed in communication with the test subject fuel cell, the fuel feed having a temperature, a humidity, a flow rate and a pressure, wherein at least one of the temperature, the humidity, the flow rate and the pressure of the fuel feed is controllable by the controller, and an oxidant feed in communication with the test subject fuel cell, the oxidant feed having a temperature, a humidity, a flow rate and a pressure, wherein at least one of the temperature, the humidity, the flow rate and the pressure of the oxidant feed is controllable by the controller, wherein the controller monitors the performance of the test subject fuel cell in response to the fuel feed and the oxidant feed.

In another aspect, the disclosed fuel cell test system may include a housing defining an insulated test chamber and an opening extending into the test chamber, the test chamber being accessible by way of a chamber door connected to the housing, the opening being filled with a removable filler material, a controller received within the housing, a test subject fuel cell positioned in the test chamber, the test subject fuel cell being in communication with the controller to provide the controller with signals indicative of at least one of a voltage and an electric current generated by the test subject fuel cell, a fuel feed in communication with the test subject fuel cell, the fuel feed having a temperature, a humidity, a flow rate and a pressure, wherein the temperature, the humidity, the flow rate and the pressure of the fuel feed are controllable by the controller, an oxidant feed in communication with the test subject fuel cell, the oxidant feed having a temperature, a humidity, a flow rate and a pressure, wherein the temperature, the humidity, the flow rate and the pressure of the oxidant feed are controllable by the controller, and a user interface connected to the housing, wherein the controller is adapted to display the voltage and/or the electric current generated by the test subject fuel cell in response to the fuel feed and the oxidant feed on the user interface.

Other aspects of the disclosed fuel cell test system will become apparent from the following description, the accompanying drawings and the appended claims.

### BRIEF DESCRIPTION OF THE DRAWINGS

FIG. 1 is a block diagram of one aspect of the disclosed fuel cell test system;

FIG. 2 is a front elevational view of one aspect of a fuel cell testing apparatus including the fuel cell test system of FIG. 1; and

FIG. 3 is a rear elevational view of the fuel cell testing apparatus of FIG. 2.

### DETAILED DESCRIPTION

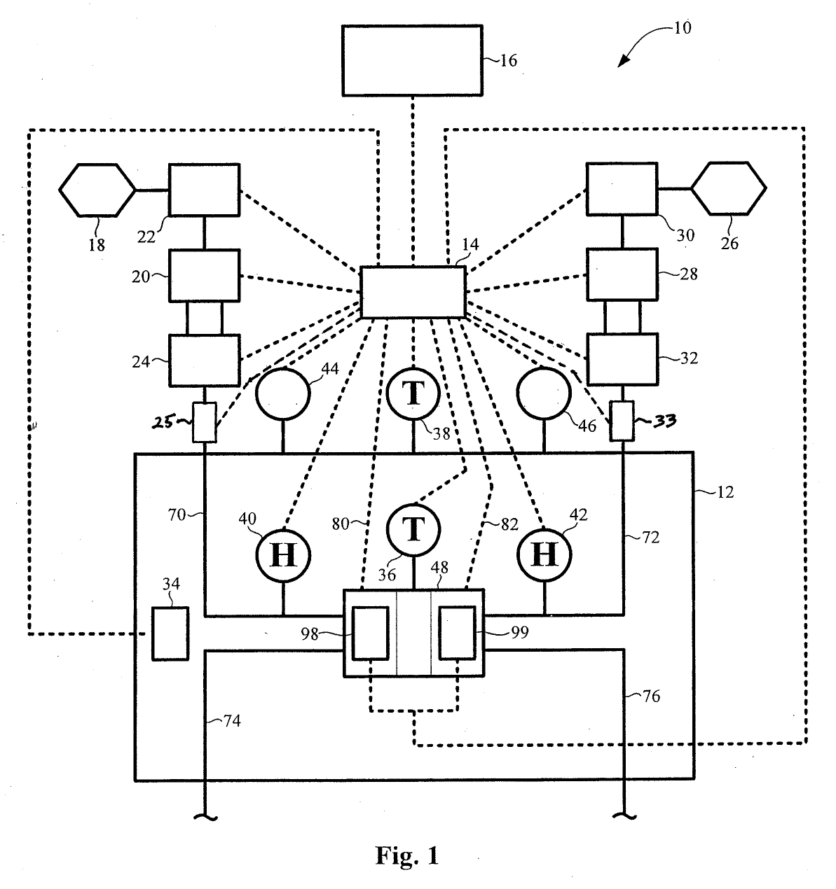

Referring to FIG. 1, one aspect of the disclosed fuel cell test system, generally designated 10, may include a test chamber 12, a master controller 14, a user interface 16, a fuel supply 18, a fuel feed flow controller 20, a fuel feed pressure controller 22, a fuel feed humidity controller 24, a fuel feed temperature controller 25, an oxidant supply 26, an oxidant feed flow controller 28, an oxidant feed pressure controller 30, an oxidant feed humidity controller 32, an oxidant feed temperature controller 33, a heater 34, test subject fuel cell heaters 98, 99, temperature sensors 36, 38 and humidity sensors 40, 42. Additional controllers and sensors may be employed without departing from the scope of the present disclosure. For example, redundant flammable gas (e.g., hydrogen) sensors 44, 46 may be positioned in the test chamber 12 to detect unsafe conditions within the test chamber 12 and initiate proper warnings and automated corrective actions.

The master controller 14 may be a processor, a computer or the like and may be loaded with or otherwise include an operating system and/or various control algorithms for controlling the system 10. The master controller 14 may be a single unit, as shown in FIG. 1, or may be comprised of multiple control units functioning in unison or otherwise. The master controller 14 may be in communication with the user interface 16, the flow controllers 20, 28, the pressure controllers 22, 30, the humidity controllers 24, 32, the temperature controllers 25, 33, the heaters 34, 98, 99 and the sensors 36, 38, 40, 42, 44, 46 by way of communication lines (see broken lines in FIG. 1). The communication lines may be hard wired or wireless communications lines, though those skilled in the art will appreciate that any means for communicating signals, such as sensor signals and control signals, may be used without departing from the scope of the present disclosure. Furthermore, as used herein, the term “communication” is not limited to two-way communication and should be construed to include one-way communication, two-way communication and other appropriate forms of communication. For example, the master controller 14 may receive signals (i.e., input signals) from the user interface 16, the flow controllers 20, 28, the pressure controllers 22, 30, the humidity controllers 24, 32 and the sensors 36, 38, 40, 42, 44, 46 and may generate and communicate signals (i.e., command signals) to the user interface 16, the flow controllers 20, 28, the pressure controllers 22, 30, the humidity controllers 24, 32, the temperature controllers 25, 33 and the heaters 34, 98, 99, as needed to optimize performance of the system 10.

The test chamber 12 may be an oven-like chamber and may be sized and shaped to receive a test subject fuel cell 48, such as a proton exchange membrane (“PEM”) fuel cell or a solid oxide fuel cell (“SOFC”), and associated components of the system 10 therein. For example, the test chamber 12 may be formed as a three-dimensional rectilinear volume, though those skilled in the art will appreciate that the test chamber 12 may have various shapes and geometries. The walls of the test chamber 12 may be generally rigid and may be formed from, lined with or otherwise include insulating materials. In one aspect, the insulating material that lines the test chamber 12 electrically and thermally isolates the test chamber to protect operators from voltage, current and thermal burns. In another aspect, the walls of the test chamber 12 may be lined with a generally white material to assist with vision inside the test chamber 12. Non-limiting examples of suitable insulating materials include melamine foam sheet insulation, fiberglass sheet insulation and the like.

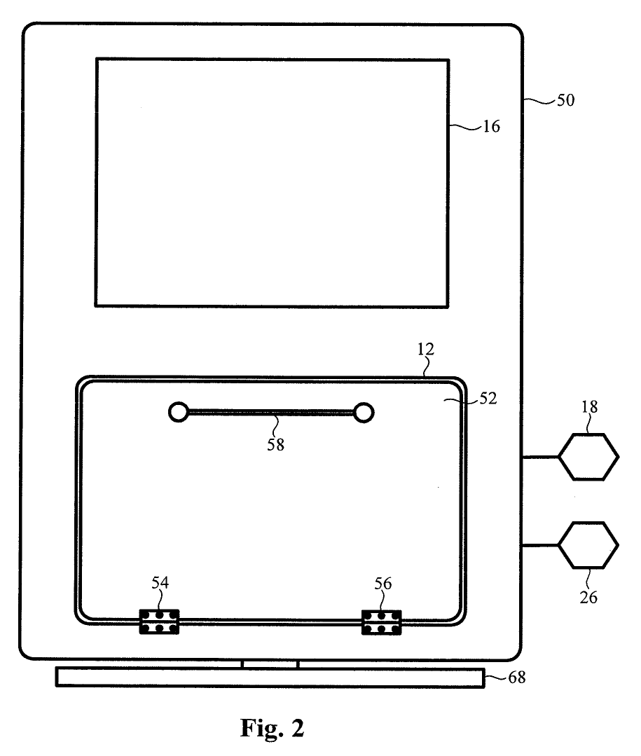

Referring to FIG. 2, the test chamber 12 may be defined by, formed in or otherwise positioned in an apparatus housing 50. A chamber door 52 may provide access to the test chamber 12 through a test chamber door opening and may be formed from, lined with or otherwise include an insulating material. For example, the chamber door 52 may be formed from thermal pane sealed glass fronted with polycarbonate. In one aspect, the chamber door 52 may be pivotally connected to the housing 50 with hinges 54, 56 and may include a handle 58 to facilitate opening and closing the chamber door 52 to provide access to the test chamber 12. In another aspect, the chamber door 52 may be secured to the housing 50 with a rubber “T” handle and a stainless steel latch on either side of the door 52. A gasket (not shown) may be positioned between the chamber door 52 and the housing 50 to provide a thermal seal.

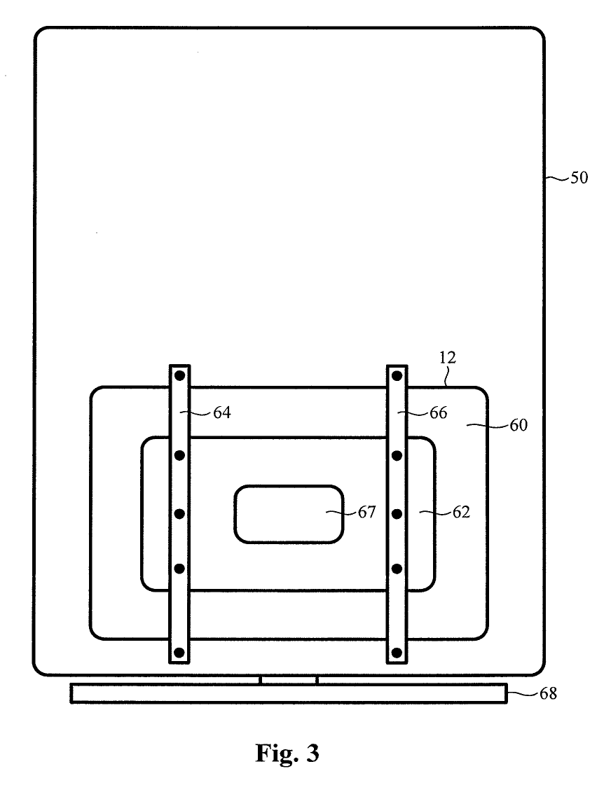

In one aspect, the test chamber 12 may include a safety feature adapted to facilitate the safe release of high pressure gases from the test chamber 12 in the event of an ignition or explosion within the test chamber 12. Referring to FIG. 3, an example of such a safety feature may include openings 60, 67 through one or more walls of the test chamber 12 to provide a low resistance exit route for high pressure gases formed in the test chamber 12. For example, as shown in FIG. 3, opening 60 may be an annular-type opening. The openings 60, 67 may be filled with an insulating material by press fitting the insulating material into the openings 60, 67 such that, in the event of an explosion, the insulating material is blown out of the openings 60, 67 and the high pressure gases are permitted to escape through the openings 60, 67.

The location of the openings 60, 67 may be selected to directed high pressure gases away from personnel and equipment. Therefore, the location of the openings 60, 67 may be dictated by the site where the system 10 will be used. For example, the openings 60, 67 may be positioned in the rear of the housing 50, as shown in FIG. 3, to directed high pressure ignition or explosion gases through the rear of the housing, or at the top of the housing 50 to direct high pressure ignition or explosion gases upward. Furthermore, the size and shape of the openings 60, 67 may be selected to minimize resistance to escaping high pressure ignition or explosion gases. While an annular opening 60 is shown in FIG. 3, those skilled in the art will appreciate that the size and shape of the opening 60 necessary to achieve a safe blow-out may be dictated by various factors, such as the overall size and shape of the test chamber 12 and the overall size and shape of the housing 50.

For example, the annular opening 60 shown in FIG. 3 may be formed by exposing the test chamber 12 through the housing 50 and securing a wall section 62 to the housing 50 using support bars 64, 66. The wall section 62 may define the second opening 67. The support bars 64, 66 may be connected to the wall section 62 and the housing 50 using screws, rivets, welding or any other available means. The annular opening 60 between the housing 50 and the wall section 62 may be filled with insulating material by press fitting the insulating material into the annular opening 60.

The housing 50 may be formed as a generally compact, bench-top unit or as a stand-alone unit. In one aspect, the housing 50 may be mounted on a 360° swivel base 68 to facilitate positioning, accessing and manipulating the test chamber 12, the user interface 16 and all sides of the housing 50. A shelf may be formed in or connected to the housing and provided beneath the test chamber 12 to provide additional work space for assembling and/or disassembling the test subject fuel cell.

As shown in FIG. 2, the user interface 16 may be mounted on, connected to or otherwise associated with the housing 50. In one aspect, the user interface 16 may include a visual display, such as a monitor, a display screen or the like, and an input device, such as a keyboard, buttons, knobs, a mouse or the like. The user interface 16 may facilitate communication between a user and the master controller 14. For example, the user interface 16 may facilitate manipulating various inputs, such as operating conditions and testing parameters, and may display test progress and test results.

Referring to FIG. 1, the fuel supply 18 may be a supply of fuel on which the test subject fuel cell 48 operates and the oxidant supply 26 may be a supply of oxidant on which the test subject fuel cell 48 operates. For example, the fuel supply 18 may be a generator or cylinder of gaseous fuel, such as gaseous hydrogen, and the oxidant supply 26 may be a generator or cylinder of gaseous oxidant, such as oxygen or air. As shown in FIG. 2, the fuel supply 18 and oxidant supply 26 may be connected to the housing 50. The connections may be made with various connecting devices.

Referring to FIG. 1, the fuel feed pressure controller 22 may control the pressure of the fuel in the fuel feed line 70. The fuel feed controller 20 may monitor and control the flow rate of fuel being supplied from the fuel supply 18 to the test subject fuel cell 48 by way of the fuel feed line 70. The fuel feed controller 20 may be a mass flow controller and may include a mass flow sensor and a controllable valve. For example, the fuel feed controller 20 may be a controllable mass flow controller. The fuel feed humidity controller 24 may be controlled in response to humidity signals received from the humidity sensor 40. The fuel feed temperature controller 25 may control the temperature of the humidified fuel in the fuel feed line 70 between the fuel feed humidity controller 24 and the test chamber 12. For example, the fuel feed temperature controller 25 may be a heating jacket received over the fuel feed line 70.

In one aspect, the fuel feed humidity controller 24 may introduce humidity to the fuel and selectively combine humidified fuel with generally dry fuel to achieve the desired fuel humidity in the fuel feed line 70. Humidity may be introduced to the fuel using a traditional water bubble system or by passing the fuel through an ion exchange membrane tube (e.g., a NAFION® tube) submersed in water. Those skilled in the art will appreciate that the humidity sensor 40 may be positioned on the fuel feed line 70 to monitor the humidity of the fuel just before it passes to the test subject fuel cell 48. Uniquely, the system 10 may measure the humidity of the fuel feed inside the test chamber 12 where the humidification measurement is at the same temperature and within intimate proximity to the test subject fuel cell 48. The oxidant feed pressure controller 30 may control the pressure of the oxidant in the oxidant feed line 72. The oxidant feed controller 28 may monitor and control the flow rate of oxidant being supplied from the oxidant supply 26 to the test subject fuel cell 48 by way of the oxidant feed line 72. For example, the oxidant feed flow controller 28 may be a controllable mass flow controller. The oxidant feed humidity controller 32 may be controlled in response to humidity signals received from the humidity sensor 42. The oxidant feed temperature controller 33 may control the temperature of the humidified oxidant in the oxidant feed line 72 between the oxidant feed humidity controller 32 and the test chamber 12. For example, the oxidant feed temperature controller 33 may be a heating jacket received over the oxidant feed line 72.

In one aspect, the oxidant feed humidity controller 32 may introduce humidity to the oxidant and selectively combine humidified oxidant with generally dry oxidant to achieve the desired oxidant humidity in the oxidant feed line 72. Humidity may be introduced to the oxidant using a traditional water bubble system or by passing the oxidant through an ion exchange membrane tube (e.g., a NAFION® tube) submersed in water. Those skilled in the art will appreciate that humidity sensor 42 may be positioned on the oxidant feed line 72 to monitor the humidity of the oxidant just before it passes to the test subject fuel cell 48. Uniquely, the system 10 may measure the humidity of the oxidant feed inside the test chamber 12 where the humidification measurement is at the same temperature and within intimate proximity to the test subject fuel cell 48.

The test subject fuel cell 48 may be connected to a test load when it is positioned in the test chamber 12. Those skilled in the art will appreciate that the test load may be anything that completes the electric circuit between the anode and the cathode of the test subject fuel cell 48. For example, the test load may be an electronically variable resistor capable of drawing the desired target current from the test subject fuel cell 48 by setting an appropriate resistance. In one aspect, as shown in FIG. 1, the test load may be provided by or otherwise associated with the controller 14.

Furthermore, the fuel feed line 70 and the oxidant feed line 72 may be connected to the appropriate inputs of the test subject fuel cell 48 and a fuel exit line 74 and an oxidant exit line 76 may be connected to the appropriate outputs of the test subject fuel cell 48. In one aspect, one or more of the lines 70, 72, 74, 76 may be connected to the test subject fuel cell 48 using various quick connect couplings (not shown). For example, the quick connect couplings may be quick connect keyed fittings.

The temperature of the test subject fuel cell 48 may be monitored by the first temperature sensor 36 and the ambient temperature of the test chamber 12 may be monitored by the second temperature sensor 38. Temperature sensors 36, 38 may be thermal couples or any other devices capable of communicating a signal indicative of temperature to the master controller 14.

The temperature within the test chamber 12 may be controlled by the heater 34. The heater 34 may be any device capable of supplying heat to the test chamber 12 and may be positioned within the test chamber 12 (e.g., along the walls of the test chamber 12) or may be external of the test chamber 12 and adapted to supply heat to the test chamber 12. For example, the heater 34 may be one or more silicon rubber resistance heaters positioned in the test chamber 12. Those skilled in the art will appreciate that additional heating devices, such as standard cartridge heaters, may be used to provide additional heat to the test chamber 12 and/or directly to the test subject fuel cell 48.

Thus, a user may set a target operating temperature for the test subject fuel cell 48 by manipulating the user interface 16 such that the master controller 14 controls the temperature of the test subject fuel cell 48 (temperature sensor 36) by controlling the heaters 34, 98, 99 and temperature controllers 25, 33, thereby maintaining the desired target temperature (temperature sensors 36, 38) of the test subject fuel cell 48 and its ambient surroundings including the humidity sensors 40, 42 and the fuel and oxidant feed lines 70, 72. Those skilled in the art will appreciate that the target operating temperature, like the target operating pressure, flow rate and humidity, may depend on the type of fuel cell being tested (e.g., SOFC v. PEM) by the system 10.

Accordingly, the master controller 14 may monitor the performance (e.g., generated voltage and/or current) of the test subject fuel cell 48 by way of communication lines 80, 82, which may connect the anode and cathode of the test subject fuel cell 48 to the master controller 14. For example, the performance of the test subject fuel cell 48 may be monitored using electrochemical impedance spectroscopy (“EIS”). The performance of the test subject fuel cell 48, whether in real-time or over time, may be displayed on the user interface 16.

At this point, those skilled in the art will appreciate that the disclosed fuel cell test system 10 may be assembled as a compact, table-top unit capable of providing uniform heating across the test subject fuel cell 48 and the associated feed lines 70, 72, thereby providing more stable fuel cell performance data, while reducing or eliminating the problems associated with condensate formation in the feed lines 70, 72. Additional advantages of the disclosed system 10 may include ultra-fast hydrogen leak detection by way of the flammable gas sensors 44, 46, intrinsically safe operation, burn protection for personnel and materials, electrical protection for personnel and equipment, precise gas leak detection and rapid detection of gas concentrations exceeding hazardous levels, protection of the unit under test from shorting or burning, a small footprint with integrated test chamber and quick connect terminals for gas and electrical connections.

Although various aspects of the disclosed fuel cell test system have been shown and described, modifications may occur to those skilled in the art upon reading the specification.

1. A fuel cell test system comprising:
a housing defining a test chamber;
a controller positioned within said housing;
a test subject fuel cell positioned in said test chamber, said test subject fuel cell being in communication with said controller to provide said controller with signals indicative of a performance of said test subject fuel cell;
a fuel feed in communication with said test subject fuel cell, said fuel feed having a temperature, a humidity, a flow rate and a pressure, wherein at least one of said temperature, said humidity, said flow rate and said pressure of said fuel feed is controllable by said controller; and
an oxidant feed in communication with said test subject fuel cell, said oxidant feed having a temperature, a humidity, a flow rate and a pressure, wherein at least one of said temperature, said humidity, said flow rate and said pressure of said oxidant feed is controllable by said controller,
wherein said controller monitors said performance of said test subject fuel cell in response to said fuel feed and said oxidant feed.

2. The fuel cell test system of claim 1 wherein said test subject fuel cell is electrically connected to a test load.

3. The fuel cell test system of claim 1 wherein said test chamber is lined with a thermal insulating material.

4. The fuel cell test system of claim 3 wherein said thermal insulating material electrically isolates said test chamber from said housing.

5. The fuel cell test system of claim 1 further comprising a chamber door connected to said housing to generally seal said test chamber.

6. The fuel cell test system of claim 5 wherein said chamber door is formed from multi-glass thermo pane safety glass.

7. The fuel cell test system of claim 1 wherein said housing defines at least one opening therein, said opening providing access to said test chamber, and wherein said opening is filled with a filler material, said filler material being blown out of said opening in the event of a sufficient pressure increase within said test chamber.

8. The fuel cell test system of claim 7 wherein said filler material includes an insulating material.

9. The fuel cell test system of claim 7 wherein said filler material is press-fit into said opening.

10. The fuel cell test system of claim 7 wherein said opening is a generally annular-type opening.

11. The fuel cell test system of claim 1 wherein said signals indicative of said performance of said test subject fuel cell include at least one of a voltage component and an electric current component.

12. The fuel cell test system of claim 1 further comprising a user interface in communication with said controller, wherein said performance of said test subject fuel cell in response to said fuel feed and said oxidant feed is displayed on said user interface.

13. The fuel cell test system of claim 12 wherein said user interface is connected to said housing to form a compact integrated test unit.

14. The fuel cell test system of claim 1 further comprising a fuel supply in fluid communication with said fuel feed and an oxidant supply in fluid communication with said oxidant feed.

15. The fuel cell test system of claim 1 further comprising a fuel feed humidity sensor positioned within said test chamber and connected to said fuel feed and a fuel feed humidity controller connected to said fuel feed, and an oxidant feed humidity sensor positioned within said test chamber and connected to said oxidant feed and an oxidant feed humidity controller connected to said oxidant feed, wherein said fuel feed humidity controller controls said humidity of said fuel feed and said oxidant feed humidity controller controls said humidity of said oxidant feed in response to command signals received from said controller, and wherein said command signals are based upon signals received by said controller from said fuel feed humidity sensor and said oxidant feed humidity sensor.

16. The fuel cell test system of claim 15 wherein said fuel feed humidity sensor is connected to said fuel feed substantially adjacent to said test subject fuel cell and said oxidant feed humidity sensor connected to said oxidant feed substantially adjacent to said test subject fuel cell.

17. The fuel cell test system of claim 15 further comprising a fuel feed temperature controller positioned between said fuel feed humidity controller and said test chamber and an oxidant feed temperature controller positioned between said oxidant feed humidity controller and said test chamber.

18. The fuel cell test system of claim 1 further comprising a fuel feed flow controller and a fuel feed pressure controller connected to said fuel feed and an oxidant feed flow controller and an oxidant feed pressure controller connected to said oxidant feed, wherein, in response to command signals received from said controller, said fuel feed flow controller is adapted to control said flow rate of said fuel feed, said fuel feed pressure controller is adapted to control said pressure of said fuel feed, said oxidant feed flow controller is adapted to control said flow rate of said oxidant feed and said oxidant pressure controller is adapted to control said pressure of said oxidant feed.

19. The fuel cell test system of claim 1 further comprising a first temperature sensor positioned to measure a temperature within said test chamber and a second temperature sensor positioned to measure a temperature of said test subject fuel cell, wherein said first and second temperature sensors are in communication with said controller.

20. The fuel cell test system of claim 1 further comprising at least one heater positioned to heat said test chamber, wherein said heater is actuated in response to command signals received from said controller.

21. The fuel cell test system of claim 1 further comprising at least one heater connected to said test subject fuel cell, wherein said heater is actuated in response to command signals received from said controller.

22. The fuel cell test system of claim 1 further comprising at least one flammable gas sensor positioned in said test chamber, wherein said flammable gas sensor is in communication with said controller.

23. A fuel cell test system comprising:
a housing defining an insulated test chamber, said insulated test chamber including a chamber door opening and a second opening, said second opening being filled with a removable filler material;
a chamber door being connectable to said chamber door opening to substantially seal said test chamber;
a controller contained within said housing;
a test subject fuel cell positioned in said test chamber and electrically connected to a test load such that signals indicative of at least one of a voltage and an electric current generated by said test subject fuel cell are communicated to said controller;
a fuel feed in communication with said test subject fuel cell, said fuel feed having a temperature, a humidity, a flow rate and a pressure, wherein said temperature, said humidity, said flow rate and said pressure of said fuel feed are controllable by said controller;
an oxidant feed in communication with said test subject fuel cell, said oxidant feed having a temperature, a humidity, a flow rate and a pressure, wherein said temperature, said humidity, said flow rate and said pressure of said oxidant feed are controllable by said controller; and
a user interface connected to said housing, wherein said controller is adapted to display said at least one of said voltage and said electric current generated by said test subject fuel cell in response to said fuel feed and said oxidant feed on said user interface.
